(19) United States
(12) Patent Application Publication
(10) Pub. No.: US 2009/0294898 A1
(43) Pub. Date: Dec. 3, 2009

(54) MICROSTRUCTURE DEVICE INCLUDING A METALLIZATION STRUCTURE WITH SELF-ALIGNED AIR GAPS BETWEEN CLOSELY SPACED METAL LINES

(76) Inventors: Frank Feustel, Dresden (DE); Thomas Werner, Moritzburg (DE); Kai Frohberg, Niederau (DE)

Correspondence Address: WILLIAMS, MORGAN & AMERSON, 10333 RICHMOND, SUITE 1100, HOUSTON, TX, 77042, US

(21) Appl. No.: 12/400,983

(22) Filed: Mar. 10, 2009

(30) Foreign Application Priority Data
May 30, 2008 (DE) 10 2008 026 134.3

(51) Int. Cl. H01L 23/58; H01L 21/764

(52) U.S. Cl. 257/522; 438/421; 257/E21.573

(57) ABSTRACT

Air gaps may be provided in a self-aligned manner with sub-lithography resolution between closely spaced metal lines of sophisticated metallization systems of semiconductor devices by recessing the dielectric material in the vicinity of the metal lines and forming respective sidewall spacer elements. Thereafter, the spacer elements may be used as an etch mask so as to define the lateral dimension of a gap on the basis of the corresponding air gaps, which may then be obtained by depositing a further dielectric material.

### BACKGROUND OF THE INVENTION

1. Field of the Invention

Generally, the subject matter of the present disclosure relates to microstructure devices, such as integrated circuits, and, more particularly, to the metallization layers including highly conductive metals, such as copper, embedded into a dielectric material of reduced permittivity.

2. Description of the Related Art

In modern integrated circuits, minimum feature sizes, such as the channel length of field effect transistors, have reached the deep sub-micron range, thereby steadily increasing performance of these circuits in terms of speed and/or power consumption and/or diversity of circuit functions. As the size of the individual circuit elements is significantly reduced, thereby improving, for example, the switching speed of the transistor elements, the available floor space for interconnect lines electrically connecting the individual circuit elements is also decreased. Consequently, the dimensions of these interconnect lines and the spaces between the metal lines have to be reduced to compensate for a reduced amount of available floor space and for an increased number of circuit elements provided per unit area.

In integrated circuits having minimum dimensions of approximately 0.35 μm and less, a limiting factor of device performance is the signal propagation delay caused by the switching speed of the transistor elements. As the channel length of these transistor elements has now reached 50 nm and less, the signal propagation delay is no longer limited by the field effect transistors, but is limited, owing to the increased circuit density, by the interconnect lines, since the line-to-line capacitance (C) is increased and the resistance (R) of the lines is also increased due to their reduced cross-sectional area. The parasitic RC time constants and the capacitive coupling between neighboring metal lines therefore require the introduction of a new type of material for forming the metallization layer.

Traditionally, metallization layers, i.e., the wiring layers including metal lines and vias for providing the electrical connection of the circuit elements according to a specified circuit layout, are formed by a dielectric layer stack including, for example, silicon dioxide and/or silicon nitride, with aluminum as the typical metal. Since aluminum suffers from significant electromigration at the higher current densities that may be necessary in integrated circuits having extremely scaled feature sizes, aluminum is being replaced by, for instance, copper, which has a significantly lower electrical resistance and a higher resistivity against electromigration. For highly sophisticated applications, in addition to using copper and/or copper alloys, the well-established and well-known dielectric materials silicon dioxide (k≈4.2) and silicon nitride (k>7) may increasingly be replaced by so-called low-k dielectric materials having a relative permittivity of approximately 3.0 and less. However, the transition from the well-known and well-established aluminum/silicon dioxide metallization layer to a copper-based metallization layer, possibly in combination with a low-k dielectric material, is associated with a plurality of issues to be dealt with.

For example, copper may not be deposited in relatively high amounts in an efficient manner by well-established deposition methods, such as chemical and physical vapor deposition. Moreover, copper may not be efficiently patterned by well-established anisotropic etch processes. Therefore, the so-called damascene or inlaid technique is frequently employed in forming metallization layers including copper lines and vias. Typically, in the damascene technique, the dielectric layer is deposited and then patterned for receiving trenches and via openings that are subsequently filled with copper or alloys thereof by plating methods, such as electroplating or electroless plating. Moreover, since copper readily diffuses in a plurality of dielectrics, such as silicon dioxide, and in many low-k dielectrics, the formation of a diffusion barrier layer at interfaces with the neighboring dielectric material may be required. Moreover, the diffusion of moisture and oxygen into the copper-based metal has to be suppressed as copper readily reacts to form oxidized portions, thereby possibly deteriorating the characteristics of the copper-based metal line with respect to adhesion, conductivity and the resistance against electromigration.

During the filling in of a conductive material, such as copper, into the trenches and via openings, a significant degree of overfill has to be provided in order to reliably fill the corresponding openings from bottom to top without voids and other deposition-related irregularities. Consequently, after the metal deposition process, excess material may have to be removed and the resulting surface topography is to be planarized, for instance, by using electrochemical etch techniques, chemical mechanical polishing (CMP) and the like. For example, during CMP processes, a significant degree of mechanical stress may be applied to the metallization levels formed so far, which may cause structural damage to a certain degree, in particular when sophisticated dielectric materials of reduced permittivity are used. As previously explained, the capacitive coupling between neighboring metal lines may have a significant influence on the overall performance of the semiconductor device, in particular in metallization levels, which are substantially “capacitance driven,” i.e., in which a plurality of closely spaced metal lines have to be provided in accordance with device requirements, thereby possibly causing signal propagation delay and signal interference between neighboring metal lines. For this reason, so-called low-k dielectric materials or ultra low-k materials may be used, which may provide a dielectric constant of 3.0 and significantly less, in order to enhance the overall electrical performance of the metallization levels. On the other hand, typically, a reduced permittivity of the dielectric material is associated with a reduced mechanical stability, which may require sophisticated patterning regimes so as to not unduly deteriorate reliability of the metallization system.

The continuous reduction of the feature sizes, with gate lengths of approximately 40 nm and less, may demand even more reduced dielectric constants of the corresponding dielectric materials, which may increasingly contribute to yield loss due to, for instance, insufficient mechanical stability of respective ultra low-k materials. For this reason, it has been proposed to introduce “air gaps,” at least at critical device areas, since air or similar gases may have a dielectric constant of approximately 1.0, thereby providing a reduced overall permittivity, while nevertheless allowing the usage of less critical dielectric materials. Hence, by introducing appropriately positioned air gaps, the overall permittivity may be reduced while, nevertheless, the mechanical stability of the dielectric material may be superior compared to conventional ultra low-k dielectrics. For example, it has been proposed to introduce nano holes into appropriate dielectric materials which may be randomly distributed in the dielectric material to significantly reduce the density of the dielectric material. However, the creation and distribution of the respective nano holes may require a plurality of sophisticated process steps for creating the holes with a desired density, while at the same time the overall characteristics of the dielectric material may be changed in view of the further processing, for instance with respect to planarizing surface areas, depositing further materials and the like.

In other approaches, advanced lithography processes are additionally introduced to create appropriate etch masks for forming gaps near respective metal lines with a position and size as defined by the lithographically formed etch mask. In this case, however, additional cost-intensive lithography steps may be required, wherein the positioning and the dimensioning of the corresponding air gaps may also be restricted by the capabilities of the respective lithography processes. Since typically in critical metallization levels the lateral dimensions of metal lines and the spacing between adjacent metal lines may be defined by critical lithography steps, an appropriate and reliable manufacturing sequence for providing intermediate air gaps may be difficult to be achieved on the basis of the available lithography techniques.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to methods and devices in which air gaps may be positioned between closely spaced metal regions with sub-lithography resolution, thereby enabling the reduction of the overall permittivity in a reliable and reproducible manner while avoiding cost-intensive sophisticated lithography processes. For this purpose, a positioning and dimensioning of the respective air gaps to be formed in a dielectric material of a metallization level may be accomplished on the basis of deposition and etch processing without applying critical lithography techniques, while also providing a high degree of flexibility in varying the size of the air gaps. In some illustrative aspects disclosed herein, critical device areas in the metallization level may be selected for receiving air gaps, while other device areas may be covered by an appropriate mask, which may, however, be formed on the basis of uncritical process conditions. Consequently, appropriate dielectric materials providing the desired characteristics may be used, while the reliable and reproducible formation of the air gaps at critical device areas in the metallization level may enable an adjustment of the overall permittivity in accordance with device requirements. For example, the metallization levels of integrated circuits including circuit elements of critical dimensions of 40 nm and less may be manufactured with a reduced permittivity, at least locally, while, in total, the mechanical integrity of the metallization level may be enhanced by avoiding extremely sophisticated and critical low-k dielectric materials.

One illustrative method disclosed herein comprises forming a recess in a dielectric material of a metallization layer of a semiconductor device, wherein the recess extends between two neighboring metal regions formed in the dielectric material. Furthermore, a spacer element is formed on sidewalls of the recess and a gap is formed between the two neighboring metal regions by using the spacer element as an etch mask.

A further illustrative method disclosed herein comprises forming a recess between a first metal line and a second metal line, wherein the first and second metal lines are formed in a dielectric material of a metallization layer of a microstructure device. The method further comprises defining a reduced width of the recess by depositing a spacer layer in the recess. Finally, the method comprises forming a gap between the first and second metal lines on the basis of the reduced width.

One illustrative microstructure device disclosed herein comprises a first metal line formed in a dielectric material of a metallization layer and a second metal line formed in the dielectric material of the metallization layer laterally adjacent to the first metal line. The device further comprises an air gap located in the dielectric material between the first and second metal lines. Furthermore, a first spacer element is formed on a portion of a first sidewall of the first metal line, wherein the first sidewall faces a second sidewall of the second metal line. Finally, the device comprises a second spacer element that is formed at a portion of the second sidewall of the second metal line.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a microstructure device, for instance, an integrated circuit, comprising a device level and a metallization system, which is to receive air gaps between closely spaced metal lines, according to illustrative embodiments;

FIGS. 1b-1f schematically illustrate cross-sectional views of a portion of the metallization system of the device of FIG. 1a during various manufacturing stages in forming air gaps between neighboring metal lines, according to illustrative embodiments;

FIG. 1g schematically illustrates a portion of the metallization system of the device of FIG. 1a with a spacer layer in combination with an etch stop layer, according to further illustrative embodiments;

FIGS. 1h-1j schematically illustrate cross-sectional views of a portion of the metallization system including an etch control layer for controlling an etch process for forming recesses, according to still further illustrative embodiments;

FIGS. 1k-1m schematically illustrate a portion of the metallization system of the device of FIG. 1a with a “buried” etch control layer for defining a depth of an intermediate gap in closely spaced metal regions, according to yet further illustrative embodiments;

FIGS. 1n-1o schematically illustrate cross-sectional views of a portion of the metallization system when removing sidewalls spacers of metal lines after forming an intermediate gap between closely spaced metal lines, according to further illustrative embodiments; and

FIGS. 1p-1q schematically illustrate cross-sectional views of a portion of the metallization system of the device of FIG. 1a during various manufacturing stages in selectively forming an air gap between metal regions in critical device areas, while covering other device areas by a mask, according to yet further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides techniques and microstructure devices, for instance, integrated circuits, in which the electrical performance of a metallization system may be enhanced by providing air gaps in the vicinity of critical metal regions, such as metal lines, without requiring sophisticated lithography techniques. That is, the positioning and the dimensioning of the air gaps may be accomplished on the basis of deposition and etch processes without additional lithography masks so that the size of the air gaps may be selected without being restricted by the lithography capabilities. The corresponding air gaps may thus be provided as self-aligned areas in the vicinity of metal lines, thereby reducing the overall permittivity of a space between metal regions, which may therefore enhance electrical performance of the metallization system even for extremely reduced device dimensions, as may be required in technology standards with critical dimensions in the transistor level of 40 nm and significantly less. In some illustrative embodiments, the self-aligned manufacturing sequence may be restricted to desired critical device areas by providing an appropriate mask, which may be formed on the basis of a non-critical lithography process. Consequently, a reliable and reproducible positioning and dimensioning of air gaps may be accomplished, at least in critical device areas, while nevertheless reducing yield loss that may conventionally be associated with critical material characteristics of ultra low-k dielectric materials.

In some illustrative aspects disclosed herein, the positioning and dimensioning of the air gaps may be accomplished by forming a recess adjacent to metal lines in a dielectric material and subsequently creating spacer elements on exposed sidewall portions of the recess, which may then be used as an etch mask, thereby substantially determining the lateral size of corresponding gaps that may be formed between closely spaced metal regions. Consequently, the dimension and the position of the air gaps may be defined on the basis of the process sequence for forming the sidewall spacer elements, thereby enabling the positioning and dimensioning with a degree of accuracy as provided by the associated deposition and etch processes. Hence, even lateral dimensions with sub-lithography resolution may be obtained in a reliable and reproducible manner, thereby providing substantially uniform electrical performance of the corresponding metallization levels. By locally varying the process conditions during the above-described sequence, the characteristics of the air gaps and thus of the electrical behavior may be varied in accordance with device requirements, wherein even a creation of air gaps may be suppressed in certain device levels, if desired. In other illustrative aspects disclosed herein, the surface topography created after the recessing of the dielectric material and the subsequent deposition of a spacer layer may be used in order to form a desired gap between neighboring metal regions, wherein the creation of distinct sidewall spacers may not be necessary. Furthermore, the techniques disclosed herein provide a high degree of flexibility in specifically adjusting the characteristics of the air gaps, for instance, by varying the depth of the recesses, selecting an appropriate thickness of the spacer layer, varying the depth of the gap etched by using the sidewall spacer elements as etch mask and the like. In other illustrative embodiments, an enhanced degree of uniformity and accuracy may be accomplished by providing one or more etch stop or etch control layers at appropriate height levels within the dielectric material in order to precisely determine a depth of the recess and/or a depth of the subsequently formed gap, without significantly contributing to overall process complexity. In still other illustrative embodiments, the overall characteristics of the metal lines may be modified by providing at least a portion of the spacer layer in the form of a conductive material, which may thus contribute to an overall enhancement of the electrical performance of the metal lines, for instance, with respect to conductivity, resistance against electromigration and the like.

Since the present disclosure relates to techniques which may enable the positioning and dimensioning of air gaps with sub-lithographical resolution, the principles disclosed herein may be highly advantageously applied to sophisticated semiconductor devices including transistor elements of the 45 nm technology or the 22 nm technology and beyond. The principles disclosed herein, however, may also be applied to less critical microstructure devices so that the present disclosure should not be considered as being restricted to specific critical device dimensions unless such restrictions are explicitly set forth in the appended claims.

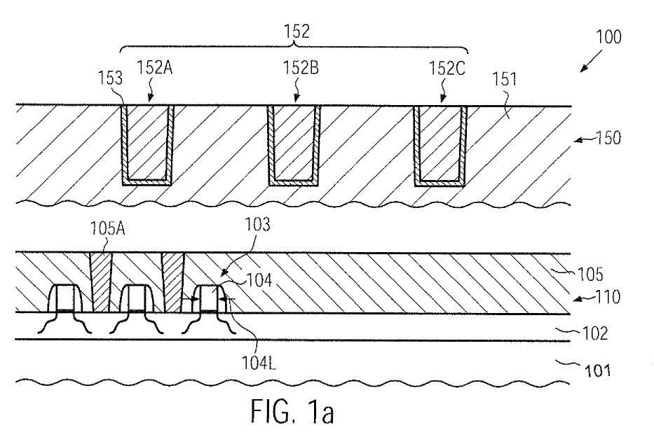

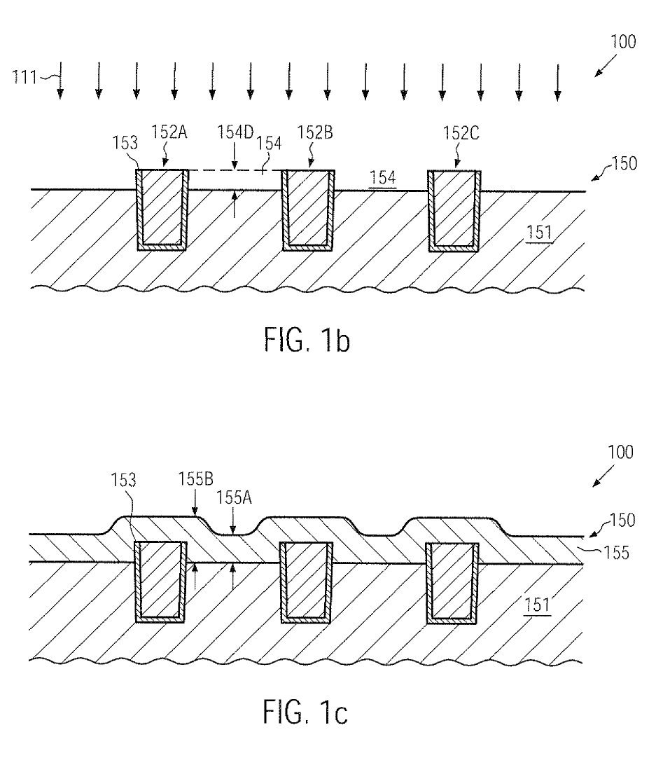

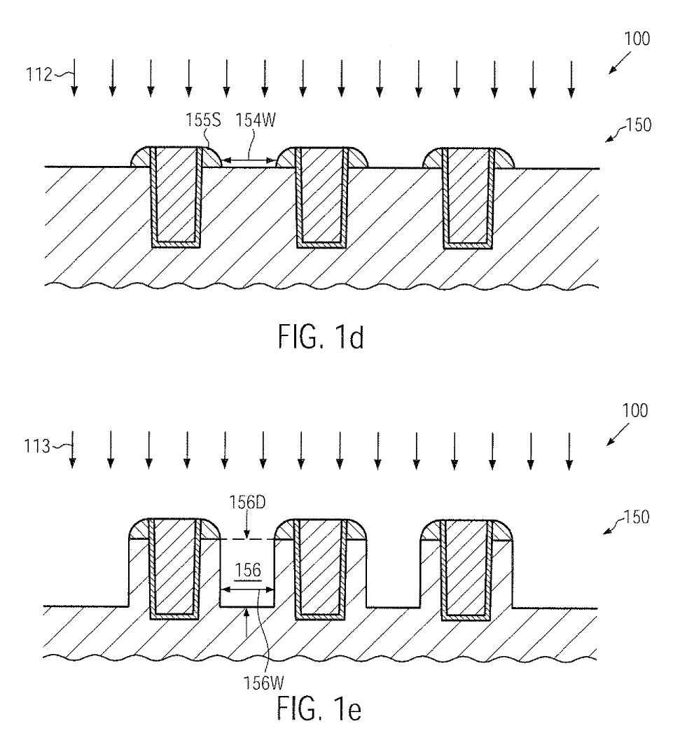

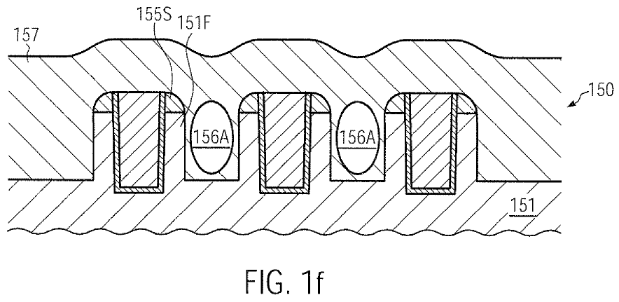

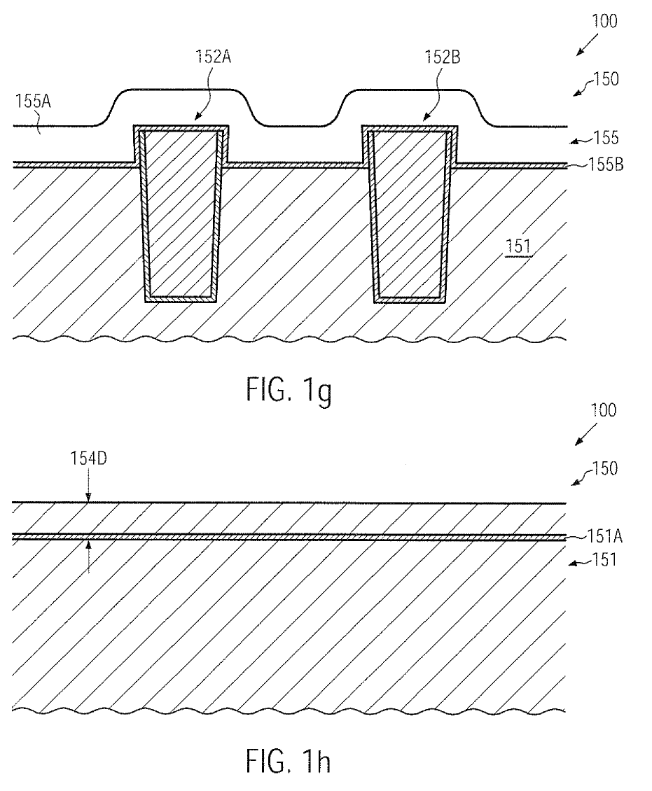

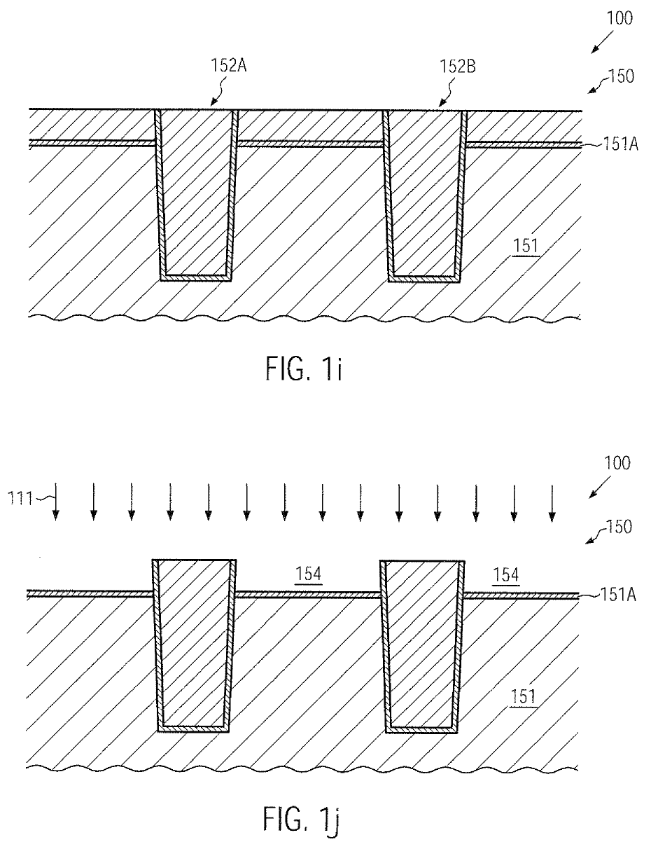

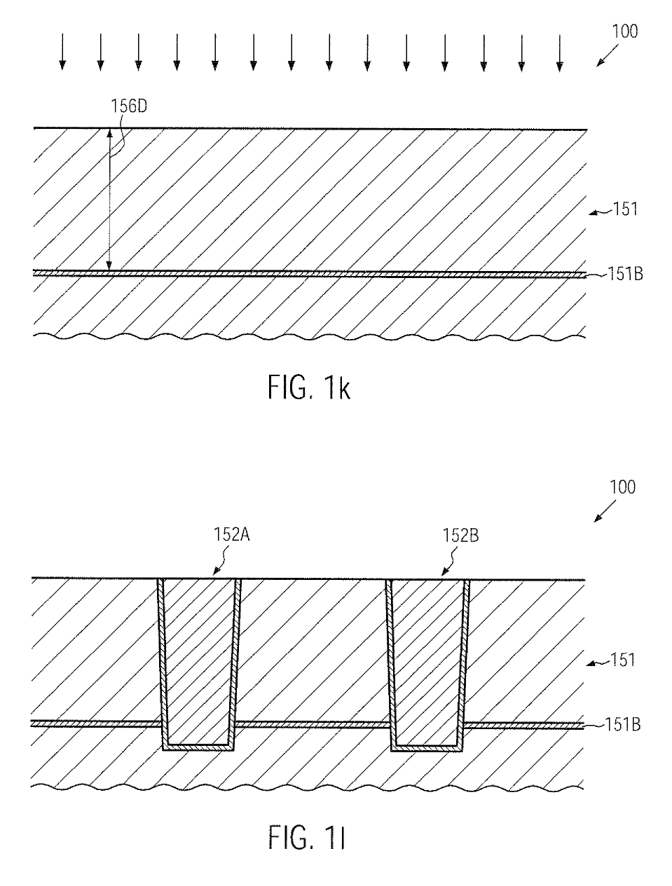

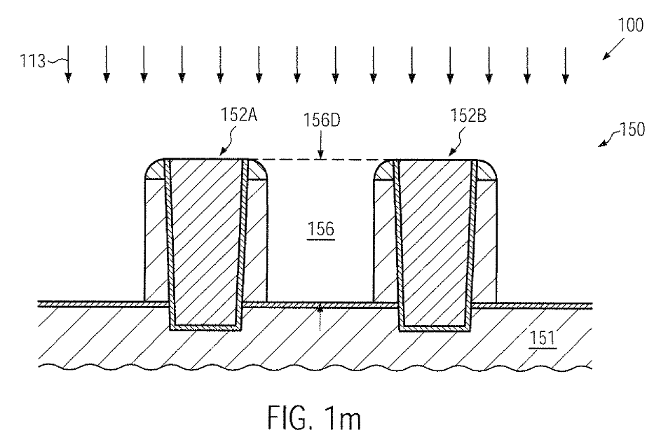

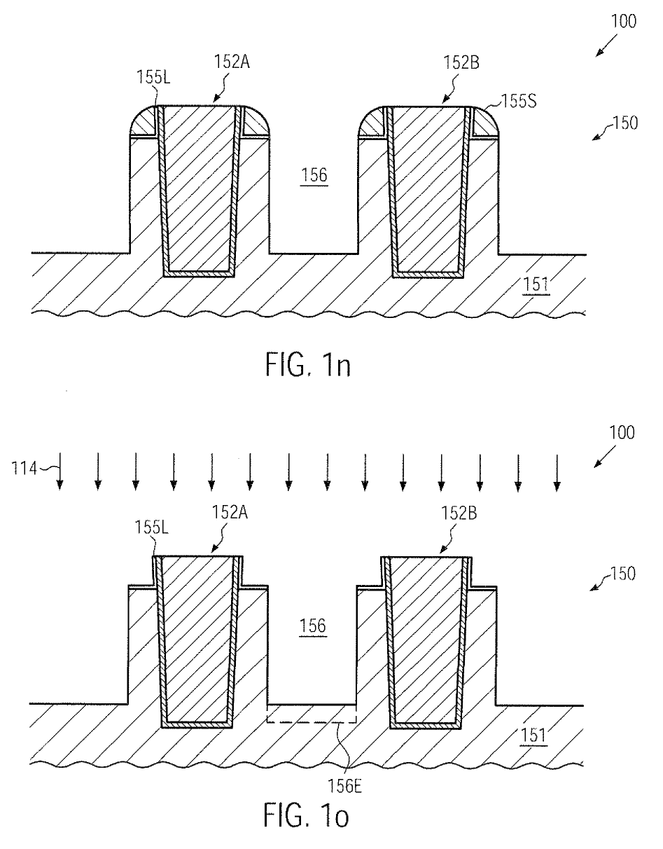

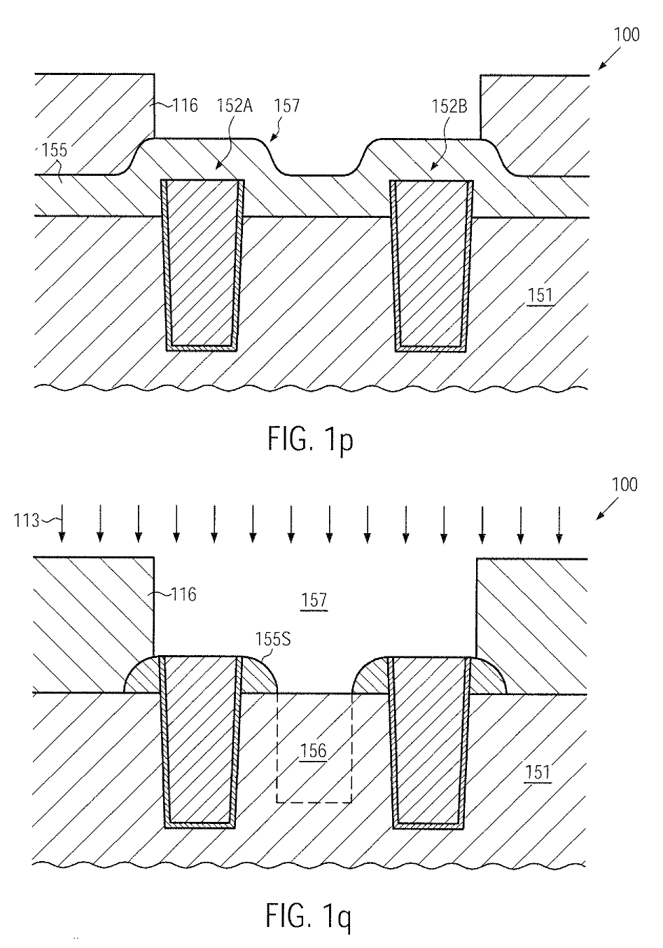

FIG. 1a schematically illustrates a cross-sectional view of a microstructure device 100 which, in the embodiment shown, may be represented by an integrated circuit including a plurality of circuit elements, such as transistors, capacitors, resistors and the like. In this case, the device 100 may comprise a device level 110, in which a plurality of circuit elements 103, such as transistors and the like, may be formed above a substrate 101. For example, the substrate 101 may represent a semiconductor substrate, an insulating substrate having formed thereon an appropriate semiconductor layer 102, in and above which may be formed the circuit elements 103. In other cases, at least partially, a buried insulating layer may be provided between the semiconductor layer 102 and the substrate 101 so as to define a silicon-on-insulator (SOI) configuration. It should be appreciated that the semiconductor material of the layer 102 may comprise any appropriate material, such as silicon, germanium, silicon/germanium mixture, compound semiconductor materials and the like, as may be required in accordance with device characteristics. The circuit elements 103, when provided in the form of transistor elements, may comprise a gate electrode structure 104 which may affect the overall characteristics and which may have a critical lateral dimension, indicated as 104L, which may be approximately 50 nm and less, such as 30 nm and less in highly sophisticated semiconductor devices. The device level 110 may further comprise a contact level 105, which may be considered as an interface between the circuit elements 103 and a metallization system 150. The contact level 105 may comprise any appropriate dielectric material, such as silicon dioxide, silicon nitride and the like, in combination with contact elements 105A which provide the electrical connection between contact areas of the circuit elements 103 and metal regions in the metallization system 150. It should be appreciated that the configuration of the device level 110 may vary depending on the overall device requirement and the principles disclosed herein should not be considered as being restricted to specific device architectures, unless such restrictions are explicitly set forth in the appended claims.

As previously explained, typically, one or more electrical connections may be associated with each of the circuit elements 103, which may thus require a plurality of metallization layers for establishing the electrical connections corresponding to the circuit layout under consideration wherein, for convenience, a portion of a single metallization layer may be illustrated as the metallization system 150. It should be appreciated, however, that below and/or above the metallization layer 150 one or more additional metallization layers may be provided, depending on the overall complexity of the device 100. For any of these additional metallization layers, the same criteria may apply as will be described later on with reference to the metallization layer 150. The metallization layer 150 may comprise a dielectric material 151 which may be provided in the form of any appropriate material or material composition to obtain the desired electrical and mechanical characteristics. For example, the dielectric material 151 may comprise a material having a moderately low permittivity while also providing sufficient mechanical robustness in view of the further processing of the device 100, as previously explained. Since the final permittivity of the metallization layer 150 may be adjusted, at least locally, on the basis of air gaps to be formed in certain locations, the selection of an appropriate dielectric material may preferably be based on the compatibility in view of the subsequent processing rather than a minimum dielectric constant. For instance, a plurality of well-established dielectric materials with a moderately low dielectric constant in the range of approximately 4.0-2.5 may be used in combination with the metallization layer 150. For example, doped silicon dioxide, silicon carbide, a plurality of silicon, oxygen, carbon and hydrogen-containing materials and the like, may be used. Also, appropriate polymer materials may be used for the metallization layer 150, as long as the desired compatibility with the further processing may be achieved. It should be appreciated that the dielectric material 151 may comprise a plurality of different materials, depending on the overall device and process requirements. The metallization layer 150 may further comprise a plurality of metal regions 152A, 152B, 152C which may, for instance, represent metal lines including a highly conductive metal, such as copper and the like, when enhanced performance with respect to conductivity, resistance against electromigration and the like is required. In other cases, other metals, such as aluminum, copper alloys, silver and the like, may be used if compatible with the device characteristics. The metal regions 152A, 152B, 152C, which may also collectively be referred to as metal regions 152, may comprise a barrier layer 153 which may contain, in some illustrative embodiments, two or more sub-layers so as to provide enhanced metal confinement and integrity of the metal with respect to a reaction with reactive components, which may be present in minute amounts within the dielectric material 151.

As previously explained, reactive metals such as copper may require appropriate barrier materials in order to maintain integrity of the copper material and also suppress undue out-diffusion of copper into the surrounding dielectric material 151. In other cases, the barrier material 153 may be omitted if a direct contact of the highly conductive metal with the dielectric material 151 is considered appropriate. For example, the barrier material 153 may comprise a copper alloy, well-established metals and metal compounds, such as tantalum, tantalum nitride and the like, which may also provide enhanced electromigration behavior and mechanical robustness of the metal regions 152 during the further processing. In some illustrative embodiments, the metal regions or metal lines 152A, 152B, 152C may be considered as “closely spaced” metal regions, wherein a lateral dimension of the individual metal lines 152 may be comparable to the lateral distance between two neighboring metal lines, such as the metal lines 152A, 152B or 152B, 152C. For example, the metallization layer 150 may comprise metal lines of a width of several hundred nanometers and significantly less, such as 100 nm and less, while also spacing between neighboring metal lines may be in the same order of magnitude. For example, the metal lines 152 may have critical dimensions, i.e., dimensions that may represent the minimum lateral dimensions that may be reliably and reproducibly obtained by the corresponding lithography process in combination with associated patterning regimes. Thus, as previously indicated, the positioning and dimensioning of any air gaps between adjacent metal lines 152 may be difficult on the basis of lithography techniques.

The device 100 as shown in FIG. 1a may be formed on the basis of the following processes. The device level 110 may be formed by using well-established process techniques, wherein sophisticated lithography processes, patterning processes and the like may be used to provide the circuit elements 103 in accordance with design rules. For instance, the gate electrode structures 104 may be formed by advanced lithography and etch techniques, thereby adjusting the gate length 104L according to design rules. Furthermore, the dopant profile in the semiconductor layer 102 may be adjusted on the basis of well-established implantation techniques in combination with anneal processes. After completing the basic structure of the circuit elements 103, the contact level 105 may be formed in accordance with appropriate manufacturing techniques, for instance, by depositing a dielectric material, planarizing the same and forming contact openings therein, which may finally be filled with an appropriate conductive material so as to obtain the contact elements 105A. Thereafter, one or more metallization layers may be formed in accordance with any appropriate manufacturing technique, such as inlaid or damascene techniques, as previously described. For convenience, a manufacturing sequence may be described with reference to the metallization layer 150, in which the metal lines 152 may be formed to connect to respective vias (not shown), which may have been formed in a lower-lying portion of the metallization layer 150 in a separate manufacturing sequence or which may be formed commonly with the metal lines 152. It should be appreciated that the present disclosure may be implemented in combination with any appropriate manufacturing sequence for forming the metal lines 152. For example, the dielectric material 151 may be deposited by any appropriate deposition technique, such as chemical vapor deposition (CVD), spin-on processes, physical vapor deposition, or any appropriate combination of these techniques. It should be appreciated that the dielectric material 151 may comprise etch stop or cap layer so as to cover metal regions of a lower-lying metallization level and/or act as an etch stop material for forming via openings or trenches for the metal lines 152, depending on the overall process strategy. Thereafter, an appropriate etch mask, possibly in the form of a hard mask, may be provided by lithography to define the lateral size of the metal regions 152. It should be appreciated that the lateral size as well as the spacing of adjacent metal lines 152 may vary significantly, even in the same metallization level, depending on the overall layout of the underlying device level 1 10. As previously discussed, the metal lines 152, as shown in FIG. 1a, may represent closely spaced metal lines in some illustrative embodiments, wherein the lateral size and the spacing may represent critical dimensions for the lithography and patterning regime under consideration. Based on the corresponding etch mask, respective openings may be formed and may be subsequently filled with an appropriate material, such as the barrier material 153, if required, and a highly conductive metal, such as copper, copper alloy, silver, aluminum and the like. The deposition of the barrier material 153 may be accomplished by using sputter deposition, electrochemical deposition, CVD, atomic layer deposition (ALD) and the like. Typically, the deposition of the highly conductive metal may be accomplished on the basis of electrochemical deposition techniques, such as electroless deposition, electroplating and the like. Thereafter, any excess material, such as the highly conductive material and residues of the barrier material 153, which may also comprise a conductive material, may be removed by any appropriate removal process, such as CMP and the like.

FIG. 1b schematically illustrates the device 100 in a further advanced manufacturing stage wherein, for convenience, the metallization layer 150 is illustrated without any underlying metallization layers and the device level 1 10. As illustrated, the device 100 is exposed to an etch ambient 111 designed to remove material of the dielectric layer 151 selectively to the metal regions 152A, 152B, 152C. For this purpose, any appropriate wet chemical or plasma-assisted etch recipe may be used, which may exhibit the desired etch selectivity. For instance, as previously explained, copper-based material may be difficult to be removed on the basis of well-established plasma-assisted etch recipes and thus may provide a desired etch selectivity with respect to a plurality of plasma assisted etch chemistries for removing the material of the layer 151. In other cases, the metal lines 152A, 152B, 152C may comprise a conductive cap layer (not shown), for instance comprised of respective alloys or metal compounds, to provide copper confinement and enhanced electromigration behavior. For instance, respective alloys, such as cobalt, phosphorous, tungsten and the like, may also provide a pronounced etch selectivity with respect to etch recipes for removing dielectric materials, such as silicon-based materials, a plurality of polymer materials and the like. Depending on the etch resistance of the barrier material 153, highly isotropic etch techniques, such as wet chemical etch techniques, also may be used during the process 111 in order to remove material of the dielectric layer 151. During the process 111, recesses 154 may be formed within an exposed portion of the dielectric material 151. A depth 154D of the recesses 154 may be adjusted on the basis of etch time during the process 111 for a given removal rate, which may be determined on the basis of experiments and the like. In other cases, the depth 154D may be adjusted on the basis of etch control materials, as will be described later on in more detail. In some illustrative embodiments, the depth 154D of the recesses 154 may be selected so as to expose an upper portion of the metal lines 152A, 152B, 152C up to a depth that may be less than half the thickness of the metal lines 152A, 152B, 152C. In this case, reduced process time during the process 111 may be accomplished. In other cases, the depth 154D may be selected to any other appropriate value, depending on the overall requirements and the conformal deposition capability of a subsequent deposition process for forming a spacer layer.

FIG. 1c schematically illustrates the device 100 in a further advanced manufacturing stage. As illustrated, a spacer layer 155 is formed above the dielectric layer 151 and thus within the recesses 154, wherein, however, a thickness of the layer 155 is selected so that a substantially conformal deposition behavior may be obtained, resulting in a surface topography in which a thickness of the layer 155, indicated as 155A, is reduced compared to a thickness 155B of the layer 155 immediately laterally adjacent to sidewalls of the metal lines 152A, 152B, 152C. The spacer layer 155 may be formed on the basis of any appropriate deposition technique, such as CVD and the like, wherein a material composition may be selected according to the overall device and process requirements. For example, well-established dielectric materials, such as silicon nitride, silicon dioxide, silicon oxynitride and the like, may be used. In other cases, the spacer layer 155 may comprise an etch stop material, as will be described later on in more detail. In even further illustrative embodiments, the spacer layer 155 may comprise a conductive material which may come into contact with the exposed portion of the metal lines 152A, 152B, 152C, thereby “re-establishing” integrity of exposed portions of these metal regions, for instance of the barrier material 153, if a certain degree of material deterioration may have occurred during the preceding etch process 111.

FIG. 1d schematically illustrates the device 100 during an etch process 112 for removing material of the spacer layer 155 so as to form spacer elements 155S at exposed sidewall portions of the metal lines 152A, 152B, 152C. The etch process 112 may be performed as a substantially anisotropic etch process, for which a plurality of well-established recipes may be available for materials, such as silicon nitride, silicon dioxide, a plurality of conductive materials and the like. In the embodiment shown in FIG. 1d, the etch process 112 may have a certain selectivity with respect to the material of the dielectric layer 151, thereby providing enhanced process uniformity for the subsequent processing of the device 100. In some illustrative embodiments, the dielectric layer 151 may have, at least at a surface thereof, an appropriate material, such as silicon dioxide, which may provide the desired etch stop capabilities, for instance with respect to etch chemistries designed to etch silicon nitride or other materials selective to silicon dioxide. In other cases, the etch stop layer may be provided within the spacer layer 155, as will be described later on.

Thus, based on the spacer elements 155S, a reduced width 154W may be obtained for the previously formed recesses 154, wherein the resulting width 154W may thus determine the lateral dimension of a gap to be formed between adjacent metal lines 152.

FIG. 1e schematically illustrates the device 100 during an etch process 113 that is performed on the basis of process parameters in order to obtain a substantially anisotropic etch behavior. For example, well-established etch recipes may be used in which the removal rate of the spacer elements 155S may be less compared to the removal rate of the material 151 so that the spacers 155S may act as an etch mask. Due to the anisotropic nature of the etch process 113, a gap 156 may be formed between adjacent metal lines 152 with a width 156W that is substantially determined by the reduced width 154W. Furthermore, a depth 156D may be adjusted on the basis of the process time of the etch process 113 for a given removal rate and may be adjusted in accordance with device requirements. That is, depending on the desired extension of an air gap to be formed on the basis of the gap 156 in a later manufacturing stage, the depth 156D may be adjusted by controlling the etch process 113. Consequently, the dimensions 156D, 156W of the gap 156 may be defined on the basis of deposition techniques for forming the spacer layer 155 and etch techniques for forming the recess 154 and the gap 156, without requiring lithographically formed etch masks. Moreover, the width 156W may be selected to any desired value without being restricted to the lithographical capabilities, while also the depth 156D may be freely adjusted in accordance with device and process requirements. For instance, the depth 156D may extend to a height level that may be located at any point within the vertical extension of the metal lines 152 or may even extend beyond the bottom face of the metal lines 152, if desired. In this manner, the effective permittivity of the dielectric material 151 between the closely spaced metal lines 152 may be adjusted in a self-aligned and reliable and reproducible manner by appropriately positioning and dimensioning the gap 156 without requiring cost-intensive lithography steps.

In some illustrative embodiments, the etch processes 112 and 113 may be performed as a combined etch process without requiring pronounced etch selectivity between the spacer elements 155S and the material of the layer 151. That is, the spacer layer 155 (FIG. 1c) may be formed with any appropriate material composition, for instance, substantially the same material as the layer 151 may be used as long as the pronounced surface topography may be achieved, as indicated by the thickness values 155A, 155B. Consequently, during a combined etch process, material of the spacer layer 155 may be removed and finally, at portions having the reduced thickness 155A, material of the layer 151 will be removed while the increased thickness 155B at the sidewalls of the metal lines 152 may provide the desired masking effect. Thus, also in this case, the gap 156 may be formed with a depth 156D that at least corresponds to the thickness difference between the values 155A, 155B. In other cases, when the materials of the layer 155 and the layer 151 have a different removal rate, for instance, the material of the layer 155 may etch at a slower rate, an even more pronounced depth 156D for the gap 156 may be obtained during a single etch process.

FIG. 1f schematically illustrates the device 100 in a further advanced manufacturing stage. As illustrated, a cap layer 157 comprised of any appropriate dielectric material may be formed above the metal lines 152 so as to confine respective air gaps 156A within the previously formed gaps 156. For this purpose, the layer 157 may be deposited by a conformal deposition technique, wherein the reduced aspect ratio of the gaps 156 may result in a reduced deposition rate within the previously formed gaps 156, while, at an upper portion thereof, overhangs may form and may finally result in closing the gaps 156 without significant material deposition so that the air gaps 156A may represent the dominant portion of the previously formed gaps 156. Appropriate process parameters for the deposition of the material 157 may be readily established by experiments, wherein a plurality of deposition recipes are also available for many dielectric materials, such as doped silicon dioxide, low-k material with an adequate mechanical behavior and the like. Due to the high degree of uniformity that may be achieved for defining the gaps 156, the dimension and the position of the air gaps 156A may also be obtained with a high degree of accuracy and reproducibility so that the total permittivity of the dielectric material between the closely spaced metal lines 152 may be reliably adjusted. The cap layer 157 may, in some illustrative embodiments, be provided in the form of substantially the same material as the layer 151, while, in other cases, any other appropriate material may be used, for instance, in view of a subsequently performed planarization process for reducing the surface topography of the layer 157. It should be appreciated that the creation of air gaps may be substantially avoided in device regions in which the lateral distance between adjacent metal lines may be significantly greater, as is indicated at the left-hand side and right-hand side of the metal lines 152A, 152C. In other cases, the creation of the air gaps 156A may be restricted to critical device areas by providing a corresponding mask, as will be described later on in more details.

After the deposition of the layer 157, the further processing may be continued, for instance, by planarizing the surface topography, if required, which may be accomplished by CMP and the like, wherein a top surface of the metal lines 152 may act as a stop layer, or wherein a certain amount of the layer 157 may be maintained so as to act as a cap layer and etch stop material for the further processing, for instance, for forming further metallization levels above the metallization layer 150. In still other illustrative embodiments, a CMP stop layer may be included into the cap layer 157, for instance, by first depositing a respective material, such as silicon nitride, silicon dioxide and the like, followed by a desired dielectric material, such as a material as used in the layer 151, or any other appropriate material. During the corresponding deposition sequence, the air gaps 156A may not necessarily be entirely closed by the deposition of the CMP stop material, but may remain open and may then be completely closed by the further deposition step.

Consequently, in the embodiment shown, the metal lines 152A, 152B, 152C may comprise the spacer elements 155S at an upper portion thereof, which may be formed on a fin comprised of material of the layer 151, wherein the spacers 155 S, in combination with the fin 151F, and together with material of the layer 157, may define the air gaps 156A. In some illustrative embodiments, the spacer elements 155S may be comprised of a dielectric material, such as silicon nitride, silicon dioxide and the like, as previously indicated, while, in other cases, the spacers 155S may comprise a conductive material, such as tantalum, tantalum nitride, titanium, tungsten, aluminum and the like, thereby enhancing the overall conductivity of the metal regions 152A, 152B, 152C. Providing a conductive barrier material may thus result in enhanced integrity of the metal lines if a certain degree of etch damage may have occurred during the exposure of upper sidewall portions of the metal lines 152. In some illustrative embodiments, the previously provided barrier material 153 may intentionally be removed during the process for forming the recesses 254 (see FIG. 1b) and the spacer layer 155 may be provided by any appropriate composition of dielectric and conductive materials to provide the desired barrier characteristics while also enhancing the overall conductivity of the metal lines 152A, 152B, 152C.

FIG. 1g schematically illustrates a portion of the metallization layer 150 according to further illustrative embodiments in which the spacer layer 155 may be provided in the form of two or more sub-layers 155A, 155B, wherein the layer 155B may act as an etch stop layer. For example, the layer 155A may be provided in the form of a silicon nitride material, while the layer 155B may be provided in the form of silicon dioxide so as to act as an efficient etch stop material based on well-established etch recipes. Consequently, upon forming the spacer elements 155S, the anisotropic etch process may be stopped on and within the layer 155B prior to actually performing the etch process 113 (FIG. 1e) for forming the gap 156. In this case, a high degree of uniformity may be achieved during the etch process 113 so that a desired depth of the gap 156 may be adjusted on the basis of the process time with high uniformity. In some illustrative embodiments, at least the etch stop layer 155B may be provided in the form of a conductive barrier material, such as tantalum nitride, tantalum and the like, in order to enhance metal confinement in the metal lines 152A, 152B without compromising the overall conductivity of the metal lines. During the etch process 113, portions of the etch stop layer 155B not covered by the spacer elements 155S may be reliably removed, thereby providing the electrical isolation between the metal lines 152A, 152B.

With reference to FIGS. 1h-1j, further illustrative embodiments will now be described in which the depth 154D of the recesses 154 (FIG. 1b) may be defined on the basis of an etch control or etch stop layer.

FIG. 1h schematically illustrates the device 100 in a manufacturing stage prior to the patterning of the dielectric layer 151. As illustrated, the layer 151 may comprise an etch the depth 154D of the recesses 154 to be formed in a later manufacturing stage.

FIG. 1i schematically illustrates the device 100 in a manufacturing stage similar to the stage in FIG. 1a wherein, however, the dielectric layer 151 may comprise the etch control or etch stop layer 151A. The layer 151A may be positioned at a height level that corresponds to a desired value of the depth 154D. For this purpose, during the deposition process for forming the dielectric layer 151, the deposition parameters may be appropriately selected so as to obtain the material 151A with an appropriate material composition and thickness. For instance, the dielectric material 151 may be formed by chemical vapor deposition, wherein, after achieving a certain layer thickness, at least one process parameter, for instance, the flow rate of a precursor gas and the like, may be changed so as to modify the material composition of the material deposited, thereby forming the layer 151A. In other illustrative embodiments, an appropriately designed separate deposition process may be performed to provide the layer 151A with a desired thickness and material composition. For instance, silicon dioxide, silicon nitride, silicon carbide, nitrogen-enriched silicon carbide and the like may represent appropriate candidates for the layer 151A. In still other illustrative embodiments, a surface treatment of a portion of the layer 151 previously deposited may be performed, for instance, in the form of a plasma treatment, thereby changing or otherwise modifying an exposed surface of the material deposited so far. In other cases, an indicator species may be incorporated, for instance, by plasma treatment or incorporation into the deposition atmosphere for the material 151, in order to form the layer 151A. The indicator species may represent any appropriate species which, upon being released into a respective etch ambient, may generate a pronounced endpoint detection signal which may be efficiently detected by endpoint detection systems which are typically provided in well-established plasma-assisted etch tools. The respective indicator species may be provided with moderately low concentration when a pronounced and well-detectable signal may be generated. Thus, the overall characteristics of the layer 151 may be substantially not modified while nevertheless providing enhanced control during the further processing of the device 100. After forming the etch control layer or etch stop layer 151A, the further processing may be continued by depositing material of the layer 151 so as to obtain the desired final thickness.

FIG. 1j schematically illustrates the device 100 during the etch process 111 for forming the recesses 154, wherein the process 111 may be controlled on the basis of the layer 151A, as previously explained.

With reference to FIGS. 1k-1m, further illustrative embodiments will now be described in which the depth 156D of the gaps 156 (FIG. 1e) may be defined on the basis of an etch control or etch stop layer.

FIG. 1k schematically illustrates the device 100 at a manufacturing stage prior to forming the metal regions 152A, 152B. As illustrated, the dielectric layer 151 may comprise an etch stop or etch control layer 151B positioned at a height level that corresponds to a desired value of the depth 156D. With respect to forming the dielectric layer 151, including the layer 151B, and with respect to a material composition of the layer 151B, the same criteria apply as discussed above with respect to the etch stop or etch control layer 151A. It should be appreciated that the layers 151A (not shown in FIG. 1k), 151B may both be provided in the layer 151 if control of both the depth 156D and the depth 154D (FIG. 1h) may be desired.

FIG. 1l schematically illustrates the device 100 with the metal lines 152A, 152B formed in the dielectric layer 151. In the embodiment shown in FIG. 1l, it may be assumed that the depth 156D is less than the vertical extension of the metal lines 152A, 152B. Consequently, the metal regions 152A, 152B may extend through the layer 151B. This may be accomplished by appropriately modifying the patterning sequence for forming the respective openings in the layer 151. That is, during the patterning of the layer 151, the etch front may be stopped within the layer 151B and the corresponding etch chemistry may be changed to etch through the layer 151B and, thereafter, a final etch step may be performed, for instance, on the basis of the previously used etch chemistry in order to obtain the finally desired depth of the corresponding trenches for the metal lines 152A, 152B. In this case, enhanced controllability of the etch process for patterning the metal lines 152A, 152B may be achieved since the corresponding etch stop capabilities of the layer 151B may result in an “equalization” of the etch step so that the subsequent etch step after opening the etch stop layer 151B may result in enhancing across-substrate uniformity for the trenches for the metal lines 152A, 152B. In other illustrative embodiments, the etch stop layer 151B may be positioned so as to also define the depth of the metal lines 152A, 152B if a corresponding vertical dimension of the finally obtained air gaps 156A (FIG. 1f) is compatible with the device requirements. In still other illustrative embodiments, the etch stop layer 151B may be positioned at a height level that is below the bottom of the metal lines 152B, 152B, wherein nevertheless, enhanced uniformity for creating the gaps 156 may be achieved, irrespective of the increased etch depth due to the provision of the etch stop layer 151B.

FIG. 1m schematically illustrates the device 100 during the etch process 113, thereby obtaining the gaps 156 having the desired depth 156D as determined by the etch stop layer 151B. In some illustrative embodiments, exposed portions of the etch stop layer 151B may be removed after the etch process 113 so as to not unduly modify the overall characteristics of the dielectric layer 151. Thus, a high degree of freedom in view of selecting an appropriate material for the etch stop layer 151B may be provided, substantially without affecting the overall behavior of the layer 151.

With reference to FIGS. 1n-1o, further illustrative embodiments will now be described in which the spacer elements 155S may be removed after forming the gaps 156.

FIG. 1n schematically illustrates the device 100 after performing the etch process 113 (FIG. 1e), thereby providing the gaps 156 between the closely spaced metal lines 152A, 152B. In some illustrative embodiments, as shown, the spacers 155S may include a liner material 155L, which, for instance, may be comprised of a conductive barrier material or any other appropriate material, such as a dielectric etch stop material and the like. In other cases, the spacers 155S may be provided as a single material if the desired etch selectivity between the spacers 155S and the remaining material of the layer 151 is provided.

FIG. 1o schematically illustrates the device 100 during a further etch process 114 for removing the spacer elements 155S selectively to the remaining material 151. For this purpose, any wet chemical or plasma-assisted etch recipes may be used, depending on the material composition of the layer 151 and the spacers 155S. In some illustrative embodiments, the etch process 114 may be performed with substantially no etch selectivity between the materials of the spacers 155S and the material 151, wherein the liner 155L may provide the desired etch stop capability. In this case, the finally desired depth of the gap 156 may be adjusted during the etch process 114, as indicated by the dashed lines 156E in FIG. 1o.

With reference to FIGS. 1p-1q, further illustrative embodiments will now be described in which the formation of the air gaps 156A (FIG. 1f) may be restricted to critical device areas.

FIG. 1p schematically illustrates the device 100 in a manufacturing stage prior to forming the gaps 156, for instance, after forming the spacer layer 155. As illustrated, an etch mask 116 may be provided so as to expose a critical device region 157, which may, in the embodiment shown, include at least the space between closely spaced metal lines 152A, 152B. On the other hand, the mask 116 may cover other device areas in which the formation of the air gaps 156A or a significant removal of material of the layer 151 is not desired. It should be appreciated that the etch mask 116, for instance in the form of a resist mask and the like, may be formed on the basis of lithography techniques which, however, may be less critical since the lateral dimensions of the critical device regions 157 may be greater than the desired lateral dimensions of the gaps 156 to be formed in the region 157. Thus, substantially non-critical process parameters may be used during a corresponding lithography process. In particular, alignment accuracy for defining the region 157 may be less critical since the position of the gap 156 to be formed in the region 157 is self-aligned, as previously explained. Based on the etch mask 116, both of the etch processes 112 (FIG. 1d), 113 FIG. 1e) may be performed so as to obtain the gap 156 between the metal lines 152A, 152B, as previously explained. Thereafter, the further processing may be performed by removing the mask 116 and depositing an appropriate dielectric material for forming the respective air gap 156A.

FIG. 1q schematically illustrates the device 100 according to a further illustrative embodiment in which the etch mask 116 may be provided after forming the spacer elements 155S. In this case, after the deposition of the spacer layer 155, the etch process 112 may be performed, as previously described, and thereafter the mask 116 may be formed by lithography on the basis of non-critical process conditions, as discussed above. Thereafter, the etch process 113 may be performed so as to obtain the gap 156 within the critical device region 157. After the removal of the etch mask 116, the further processing may be continued as described above.

As a result, the present disclosure provides techniques and microstructure devices in which the permittivity of a dielectric material of a metallization layer may be adjusted on the basis of air gaps, which may be provided in a self-aligned manner without requiring lithography processes for defining the position and adjusting the finally obtained size of the air gaps. Consequently, appropriate dielectric materials may be used, while nevertheless providing a reduced overall permittivity, at least within critical device regions, so that the overall handling of the metallization layer during the various manufacturing processes may be enhanced, while at the same time providing a desired low permittivity. The positioning and dimensioning of the air gaps may be accomplished on the basis of deposition and etch processes, wherein the lateral size of the air gaps may be beyond the capabilities of respective lithography techniques used for forming the microstructure device under consideration. For example, a reliable and reproducible adjustment of the overall permittivity between closely spaced metal lines of semiconductor devices may be accomplished in which transistor elements may be provided in the device level having critical dimensions of 50 nm and significantly less, such as 30 nm and less.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A method, comprising:
forming a recess in a dielectric material of a metallization layer of a semiconductor device, said recess extending between two neighboring metal regions formed in said dielectric material;
forming a spacer element on sidewalls of said recess; and
forming a gap between said two neighboring metal regions by using said spacer element as an etch mask.

2. The method of claim 1, further comprising forming a cap layer above said gap so as to maintain at least a portion of said gap as a dielectric barrier between said two neighboring metal regions.

3. The method of claim 1, wherein forming said recess comprises performing an etch process to remove material of said dielectric material selectively to said two neighboring metal regions.

4. The method of claim 1, further comprising providing a first etch control layer in said dielectric material to adjust a depth of said recess.

5. The method of claim 1, further comprising providing a second etch control layer in said dielectric material to adjust a depth of said gap.

6. The method of claim 1, further comprising removing said spacer element after forming said gap.

7. The method of claim 1, further comprising forming a mask to expose a first device region and cover a second device region, wherein said first device region comprises a space between said two neighboring metal regions.

8. The method of claim 1, wherein forming said spacer element comprises forming an etch stop layer above said dielectric material after forming said recess and forming a spacer layer on said etch stop layer.

9. The method of claim 8, wherein said etch stop layer comprises a barrier material for suppressing metal diffusion.

10. The method of claim 8, wherein said etch stop layer comprises a conductive material.

11. The method of claim 10, further comprising removing portions of said etch stop layer not covered by said spacer element.

12. The method of claim 1, wherein forming said spacer element comprises depositing a conductive material and anisotropically etching said conductive material so as to obtain said spacer element.

13. A method comprising:
forming a recess between a first metal line and a second metal line, said first and second metal lines formed in a dielectric material of a metallization layer of a microstructure device;
defining a reduced width of said recess by depositing a spacer layer into said recess; and
forming a gap between said first and second metal lines on the basis of said reduced width.

14. The method of claim 13, wherein defining said reduced width comprises forming a spacer element in said recess.

15. The method of claim 13, wherein forming said gap comprises performing an anisotropic etch process and using said spacer layer as an etch mask.

16. The method of claim 15, wherein said performing said anisotropic etch process comprises removing material of said spacer layer and said dielectric material of said metallization layer in a common process.

17. The method of claim 14, further comprising removing said spacer element after forming said gap.

18. The method of claim 13, further comprising covering a portion of said metallization layer by an etch mask and forming said gap in a non-covered portion of said metallization layer.

19. The method of claim 13, further comprising depositing a dielectric cap layer above said metallization layer after forming said gap to maintain at least a portion of said gap for reducing capacitive coupling between said first and second metal lines.

20. A microstructure device, comprising:
a first metal line formed in a dielectric material of a metallization layer;
a second metal line formed in the dielectric material of said metallization layer laterally adjacent to said first metal line;
an air gap located in said dielectric material between said first and second metal lines;
a first spacer element formed at a portion of a first sidewall of said first metal line that faces a second sidewall of said second metal line; and
a second spacer element formed at a portion of said second sidewall of said second metal line.

21. The device of claim 20, wherein said first and second spacer elements do not extend along the entire thickness of said first and second metal lines.

22. The device of claim 21, wherein said first and second spacer elements extend from a height level corresponding to a top surface of said first and second metal lines to less than half a thickness of said first and second metal lines.

23. The device of claim 20, further comprising at least some metal lines that are formed in said dielectric material of said metallization layer without an adjacent air gap.

24. The device of claim 20, further comprising transistor elements having a gate length of approximately 30 nm or less.

25. The device of claim 24, wherein a lateral size of said air gap is less than a gate length of said transistor elements.
